(19) United States
(12) Patent Application Publication
(10) Pub. No.: US 2025/0280709 A1
(43) Pub. Date: Sep. 4, 2025

(54) FOLDABLE DISPLAY DEVICE

(71) Applicant: LG Display Co., Ltd., Seoul (KR)

(72) Inventor: NaYoung SONG, Goyang-si (KR)

(73) Assignee: LG Display Co., Ltd., Seoul (KR)

(21) Appl. No.: 19/062,944

(22) Filed: Feb. 25, 2025

(30) Foreign Application Priority Data
Feb. 29, 2024 (KR) 10-2024-0030207

(51) Int. Cl. H10K 59/80; H10K 102/00

(52) U.S. Cl. CPC H10K 59/873; H10K 59/8792; H10K 2102/311

(57) ABSTRACT

A foldable display device includes a folding area and non-folding areas on both sides of the folding area, which includes folding shoulder areas on both sides to be adjacent to the non-folding area and a folding center area inside from the folding shoulder areas on both sides. The foldable display device includes a glass substrate having a first pattern corresponding to the folding area; a first bottom coating layer on a bottom surface of the glass substrate and filled in the first pattern; a light emitting diode on the glass substrate; an encapsulation layer on the light emitting diode; a plurality of color filters and a black matrix on the encapsulation layer; and a cover glass on the plurality of color filters. Any one of organic material layers located between the plurality of color filters and the cover glass includes a second pattern corresponding to the folding area.

### CROSS-REFERENCE TO RELATED APPLICATIONS

This application claims the priority of Korean Patent Application No. 10-2024-0030207 filed on Feb. 29, 2024, in the Korean Intellectual Property Office, the disclosure of which is incorporated herein by reference.

### BACKGROUND

### Technical Field

The present disclosure relates to a foldable display device, and more particularly to a foldable display device with improved rigidity, durability, and foldability.

### Discussion of the Related Art

Recently, as it enters an information era, a display field which visually expresses electrical information signals has been rapidly developed and in response to this, various display devices having excellent performances such as thin-thickness, light weight, and low power consumption have been developed. Specific examples of such a display device include a liquid crystal display device (LCD), a plasma display panel device (PDP), a field emission display device (FED), an organic light emitting display device (OLED), and the like.

Among them, the organic light emitting display device includes an anode, a cathode, and an organic light emitting layer disposed therebetween. However, the cathode is formed using a metal material having a high reflectance so that the external light is reflected by the metal material to deteriorate reflection luminosity and a contrast ratio. Therefore, in order to reduce the reflection by the external light, a polarizer is disposed below a cover member to absorb the external light. The polarizer is a film having a predetermined level of light transmittance and absorbs external light and reflected light thereof to suppress the deterioration of the contrast ratio.

In the meantime, recently, a flexible display device which is manufactured to be capable of displaying images even though the flexible display device is bent or folded like papers is attracting attention as a next generation display device. The flexible display device is classified into a unbreakable display device having a high durability, a bendable display device which is bent without being broken, a rollable display device which is rolled, and a foldable display device which is folded. Such a flexible display device has advantages in terms of space utilization, interior, and designs and has various application fields.

In such a flexible display device, a structure in which a coated polarization film which is relatively thin is applied instead of a thick polarizer has been suggested. However, there are problems in that the thickness of the coated polarization film is also large and if the thickness is reduced, a function and a display quality of the polarization film are deteriorated.

### SUMMARY

Accordingly, embodiments of the present disclosure are directed to a foldable display device that substantially obviates one or more of the problems due to limitations and disadvantages of the related art.

An aspect of the present disclosure is to provide a foldable display device which has a good foldability and durability even using a glass substrate and a cover glass.

Another aspect of the present disclosure is to provide a foldable display device for which a number of processes is reduced and a manufacturing process is simplified.

Still another aspect of the present disclosure is to provide a foldable display device which suppresses a crack and peeling generated in a coating layer above a color filter due to the folding operation.

Additional features and aspects will be set forth in the description that follows, and in part will be apparent from the description, or may be learned by practice of the inventive concepts provided herein. Other features and aspects of the inventive concepts may be realized and attained by the structure particularly pointed out in the written description, or derivable therefrom, and the claims hereof as well as the appended drawings.

To achieve these and other aspects of the inventive concepts, as embodied and broadly described herein, a foldable display device includes a folding area and non-folding areas located on both sides of the folding area which includes folding shoulder areas located on both sides so as to be adjacent to the non-folding area and a folding center area located inside from the folding shoulder areas on both sides. The foldable display device comprises a glass substrate which includes a first pattern provided so as to correspond to the folding area; a first bottom coating layer which is disposed on a bottom surface of the glass substrate and is filled in the first pattern; a light emitting diode disposed on the glass substrate; an encapsulation layer disposed on the organic light emitting diode; a plurality of color filters and a black matrix disposed on the encapsulation layer; and a cover glass disposed on the plurality of color filters. Any one of organic material layers located between the plurality of color filters and the cover glass includes a second pattern provided so as to correspond to the folding area.

Other detailed matters of the exemplary embodiments are included in the detailed description and the drawings.

According to the present disclosure, the foldable display device has a good foldability and durability even using a glass material.

According to the present disclosure, in the foldable display device, a specific pattern is formed on a glass substrate, a cover glass, and an over coating layer to improve the foldability and suppress the crack and peeling of a component.

According to the present disclosure, the foldable display device has a simple structure and a reduced number of steps of manufacturing process to be easily manufactured.

According to the present disclosure, the foldable display device improves a foldability and durability while simultaneously operating in an in-folding manner and an out-folding manner.

The effects according to the present disclosure are not limited to the contents exemplified above, and more various effects are included in the present specification.

### BRIEF DESCRIPTION OF DRAWINGS

The accompanying drawings, which are included to provide a further understanding of the disclosure and are incorporated in and constitute a part of this application, illustrate embodiments of the disclosure and together with the description serve to explain various principles. In the drawings:

FIG. 1 is a schematic plan view of a foldable display device according to an exemplary embodiment of the present disclosure;

FIG. 2 is a schematic cross-sectional view of II-II′ of FIG. 1;

FIG. 3 is a schematic cross-sectional view of a display panel of FIG. 2;

FIG. 4 is a schematic cross-sectional view of a foldable display device according to another exemplary embodiment of the present disclosure;

FIG. 5 is a schematic cross-sectional view of a foldable display device according to still another exemplary embodiment of the present disclosure;

FIG. 6 is a schematic cross-sectional view of a foldable display device according to still another exemplary embodiment of the present disclosure;

FIG. 7 is a schematic cross-sectional view of a foldable display device according to still another exemplary embodiment of the present disclosure;

FIG. 8 is a schematic cross-sectional view of a foldable display device according to still another exemplary embodiment of the present disclosure;

FIG. 9 is a schematic cross-sectional view of a foldable display device according to still another exemplary embodiment of the present disclosure;

FIG. 10 is a schematic cross-sectional view of a foldable display device according to still another exemplary embodiment of the present disclosure;

FIG. 11 is a schematic cross-sectional view of a foldable display device according to still another exemplary embodiment of the present disclosure;

FIG. 12 is a schematic cross-sectional view of a foldable display device according to still another exemplary embodiment of the present disclosure; and

FIG. 13A is a view illustrating a folding test simulation result of a foldable display device according to Embodiment 1.

FIG. 13B is a view illustrating a folding test simulation result of a foldable display device of Comparative Embodiment 1.

### DETAILED DESCRIPTION

Advantages and characteristics of the present disclosure and a method of achieving the advantages and characteristics will be clear by referring to exemplary embodiments described below in detail together with the accompanying drawings. However, the present disclosure is not limited to the exemplary embodiments disclosed herein but will be implemented in various forms. The exemplary embodiments are provided by way of example only so that those skilled in the art can fully understand the disclosures of the present disclosure and the scope of the present disclosure.

The shapes, sizes, ratios, angles, numbers, and the like illustrated in the accompanying drawings for describing the exemplary embodiments of the present disclosure are merely examples, and the present disclosure is not limited thereto. Like reference numerals generally denote like elements throughout the specification. Further, in the following description of the present disclosure, a detailed explanation of known related technologies may be omitted to avoid unnecessarily obscuring the subject matter of the present disclosure. The terms such as “including,” “having,” and “consist of” used herein are generally intended to allow other components to be added unless the terms are used with the term “only”. Any references to singular may include plural unless expressly stated otherwise.

Components are interpreted to include an ordinary error range even if not expressly stated.

When the position relation between two parts is described using the terms such as “on”, “above”, “below”, and “next”, one or more parts may be positioned between the two parts unless the terms are used with the term “immediately” or “directly”.

When an element or layer is disposed “on” another element or layer, another layer or another element may be interposed directly on the other element or therebetween.

Although the terms “first”, “second”, and the like are used for describing various components, these components are not confined by these terms. These terms are merely used for distinguishing one component from the other components. Therefore, a first component to be mentioned below may be a second component in a technical concept of the present disclosure.

Like reference numerals generally denote like elements throughout the specification.

A size and a thickness of each component illustrated in the drawing are illustrated for convenience of description, and the present disclosure is not limited to the size and the thickness of the component illustrated.

The features of various embodiments of the present disclosure can be partially or entirely adhered to or combined with each other and can be interlocked and operated in technically various ways, and the embodiments can be carried out independently of or in association with each other.

Hereinafter, a foldable display device according to exemplary embodiments of the present disclosure will be described in detail with reference to accompanying drawings.

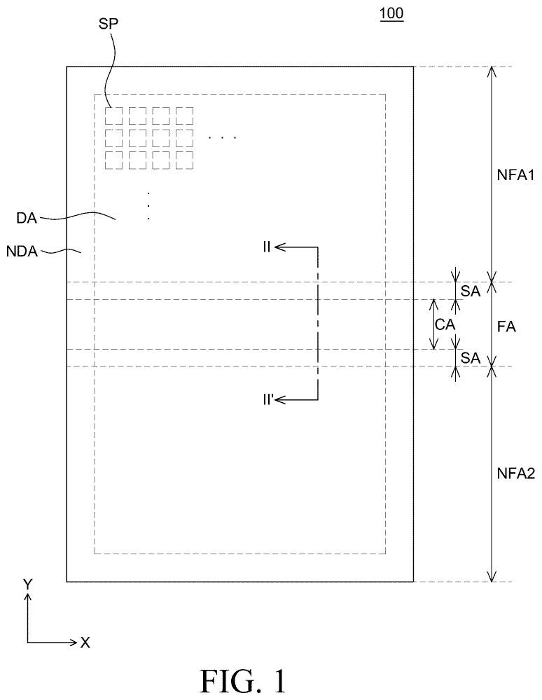

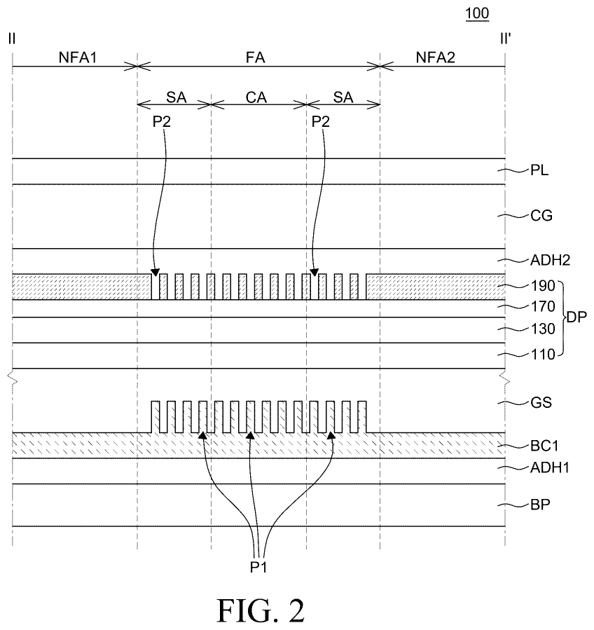

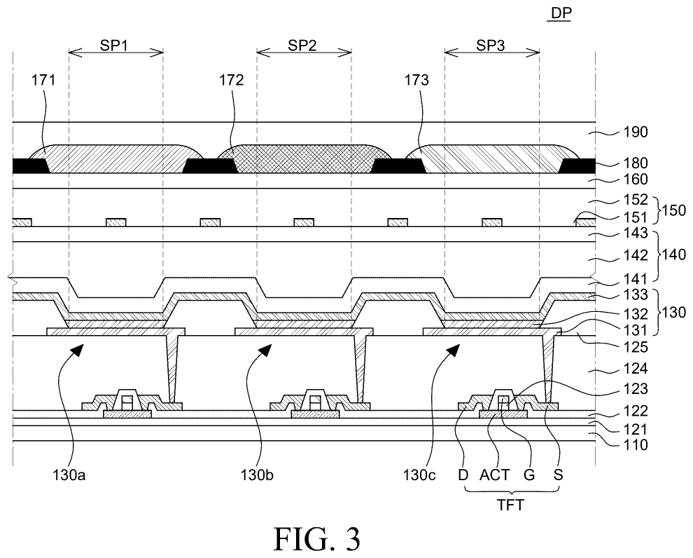

FIG. 1 is a schematic plan view of a foldable display device according to an exemplary embodiment of the present disclosure. FIG. 2 is a schematic cross-sectional view of II-II′ of FIG. 1. FIG. 3 is a schematic cross-sectional view of a display panel of FIG. 2.

Referring to FIGS. 1 and 2, a foldable display device 100 according to an exemplary embodiment of the present disclosure includes a glass substrate GS, a display panel DP, a cover glass CG, and a back plate BP. Hereinafter, for the convenience of description, the foldable display device 100 according to the exemplary embodiment of the present disclosure is assumed as an organic light emitting display device, but it is not limited thereto.

The foldable display device 100 according to the exemplary embodiment of the present disclosure may be folded at a specific angle as intended by the user. Further, the foldable display device may be fully folded or unfolded as intended by the user. The foldable display device is inwardly folded (in-folded, or inner folded) to be folded or unfolded so that the display panel is disposed inside and is outwardly folded (out-folded) to be folded or unfolded so that the display panel is disposed outside. The foldable display device 100 according to the exemplary embodiment of the present disclosure is folded by a method selected from an in-folding manner or an out-folding manner of the user. Further, in one foldable display device 100, the in-folding manner and the out-folding manner may be simultaneously implemented.

The foldable display device 100 includes a display area DA and a non-display area NDA. Further, the foldable display device 100 includes a folding area FA and non-folding areas NFA1 and NFA2. The foldable display device 100 may be divided into a display area DA and a non-display area NDA depending on whether to display an image. Further, the foldable display device 100 may be divided into a folding area FA and non-folding areas NFA1 and NFA2 depending on whether to be folded. Therefore, a partial area of the foldable display device 100 may be a display area DA and a folding area FA and the other partial area of the foldable display device 100 may be a non-display area NDA and the non-folding areas NFA1 and NFA2.

In the meantime, for the convenience of description, it is assumed that the foldable display device 100 according to the exemplary embodiment of the present disclosure is a foldable display device in which one folding area FA is disposed in only a partial area of the display area DA. However, the foldable display device 100 according to the exemplary embodiment of the present disclosure may be a display device in which a plurality of folding areas is disposed in the display area DA, but is not limited thereto.

The display area DA is an area where a plurality of pixels is disposed to substantially display images. In the display area DA, a plurality of pixels which includes an emission area to display images, a thin film transistor for driving the pixels, and a capacitor may be disposed. One pixel may include a plurality of sub pixels SP. The sub pixel SP is a minimum unit which configures the display area and each sub pixel SP may be configured to emit light of a specific wavelength band. For example, each of the sub pixels SP may be configured to emit red light, green light, blue light, or white light.

The non-display area NDA is disposed so as to enclose the display area DA. The non-display area NDA is an area where images are not substantially displayed and various wiring lines and driving ICs for driving the pixels and the driving elements disposed in the display area DA are disposed therein.

As described above, the foldable display device 100 according to the exemplary embodiment of the present disclosure may be defined as a folding area FA and non-folding areas NFA1 and NFA2 depending on whether to be foldable. The foldable display device 100 includes one folding area FA which is foldable and non-folding areas NFA1 and NFA2 excluding the folding area. The folding area FA is an area which is folded when the foldable display device 100 is folded and may be folded in accordance with a specific radius of curvature with respect to a folding axis. Here, the folding axis may be formed in the X-axis direction. The non-folding areas NFA1 and NFA2 may be located on both sides of the folding area FA along the folding direction. Here, the folding direction may refer to a Y-axis direction which is perpendicular to the folding axis. When the folding area FA is folded with respect to the folding axis, the folding area FA may form a part of a circle or an oval. At this time, a radius of curvature of the folding area FA may refer to a radius of a circle or an oval formed by the folding area FA.

The folding area FA includes a folding center area CA and a folding shoulder area SA. The folding shoulder area SA refers to an area in the folding area FA which is the most tensile point during a folding operation. The folding shoulder area SA includes a boundary between the non-folding areas NFA1 and NFA2 which are not deformed during the folding operation and the folding area FA which is deformed. The folding center area CA refers to an area between the folding shoulder areas SA located on both sides in the folding area FA.

In the meantime, even though in FIGS. 1 and 2, a structure in which the folding shoulder area SA is in contact with the non-folding areas NFA1 and NFA2 to be located in the folding area FA has been illustrated. However, the present disclosure is not limited thereto. For example, the folding shoulder area SA may be located so as to overlap the non-folding area NFA1 and NFA2 and the folding area FA to include a boundary between the non-folding area NFA1 and NFA2 and the folding area FA.

The non-folding areas NFA1 and NFA2 are areas which are not folded when the foldable display device 100 is folded. That is, the non-folding areas NFA1 and NFA2 maintain a flat surface state when the foldable display device 100 is folded. The non-folding areas NFA1 and NFA2 may extend from both sides of the folding area FA along the folding direction. At this time, the folding area FA may be defined between the non-folding areas NFA1 and NFA2. The non-folding areas NFA1 and NFA2 includes a first non-folding area NFA1 and a second non-folding area NFA2. The first non-folding area NFA1 extends from one side of the folding area FA and the second non-folding area NFA2 may extend from the other side of the folding area FA. When the foldable display device 100 is folded with respect to the folding axis, the first non-folding area NFA1 and the second non-folding area NFA2 may overlap each other.

The glass substrate GS supports the display panel DP located thereabove. The glass substrate GS may be fabricated with a plate-type alkali-free glass or non-alkali glass, but is not limited thereto.

A thickness of the glass substrate GS may be 30 μm to 200 μm or 500 μm to 150 μm. When the thickness of the glass substrate GS satisfies the above-mentioned range, the glass substrate may support the components of the foldable display device 100 and also implement the display device to be folded or bent.

A plurality of first patterns P1 is formed on the glass substrate GS so as to correspond to the folding area FA. Specifically, the glass substrate GS includes an inner surface which faces the display panel DP and an outer surface which is opposite to the inner surface. At this time, the first pattern P1 may be a concave pattern or a groove which is formed inwardly from the outer surface to allow the foldable display device 100 to be folded or bent. The first pattern P1 may have a structure in which concave portions and convex portions continuously and alternately disposed. Accordingly, the first pattern P1 may give a flexibility to the glass substrate GS.

The plurality of first patterns P1 may disperse the stress concentrated on the folding area FA during the folding. As described above, as the plurality of first patterns P1 is formed in a position corresponding to the folding area FA, it is advantageous in that the foldable display device 100 is easily folded and has an excellent resilience.

Each of the plurality of first patterns P1 may be formed to extend long in a direction parallel to the folding axis (X-axis direction in FIG. 1). That is, the first pattern P1 may be formed to extend long along the same direction as the folding axis. Therefore, the first pattern P1 may be formed to be parallel to the folding axis in the form of bar in the plan view. In the meantime, the first pattern P1 may continuously extend to the non-display area across the display area FA without being disconnected, along the same direction as the folding axis, but is not limited thereto. When the first pattern P1 extends to be parallel to the folding axis (X-axis direction), the glass substrate GS is easily bent in a direction (Y-axis direction) perpendicular to the folding axis. In contrast, the rigidity is increased to the folding axis direction (X-axis direction) due to the first pattern P1 so that the glass substrate GS is not easily bent in the folding axis direction (X-axis direction).

In the meantime, in FIG. 2, a structure in which the plurality of first patterns P1 is formed in the folding area FA with the same shape and interval has been illustrated. However, the present disclosure is not limited thereto. That is, the first patterns P1 may be formed in the folding center area CA and the folding shoulder area SA with different thicknesses, widths, and intervals. Further, the plurality of first patterns P1 may be formed in the entire folding area FA or may also be formed only a partial area of the folding area FA. That is, the plurality of first patterns P1 may be formed only in a partial area of the folding center area CA and the folding shoulder area SA.

In the meantime, in the foldable display device 100 according to the exemplary embodiment of the present disclosure, the glass substrate GS may be formed from a carrier substrate or a mother substrate which supports components disposed thereabove during the manufacturing process of the foldable display device 100. As it will be described below, the components of the display panel are sequentially laminated on the carrier substrate or the mother substrate. After completely manufacturing the display panel DP, the carrier substrate or the mother substrate are not removed, but a lower surface thereof is etched to reduce a thickness and uniformize a surface to form the glass substrate GS. In the meantime, after the process of etching the carrier substrate or the mother substrate to uniformize the thickness or the surface, a process of forming a first pattern P1 in an area corresponding to the folding area FA of the foldable display device 100 may be further added.

A first bottom coating layer BC1 is disposed below the glass substrate GS. The first bottom coating layer BC1 suppresses a shock applied from the outside from being transmitted to the display panel DP and suppresses the crack of the glass substrate GS. Specifically, the first bottom coating layer BC1 is filled in the first pattern P1 formed on the glass substrate GS and absorbs a folding stress generated on the glass substrate GS during the folding operation, and improves the foldability. Accordingly, a combination of the glass substrate GS including the first pattern P1 and the first bottom coating layer BC1 allows the foldable display device 100 to be easily bent and reinforces the rigidity to reduce a strain of the glass substrate GS. Accordingly, even though the foldable display device 100 is folded with a large curvature, the strain of the glass substrate GS is reduced to suppress creases or stains from being visible. The first bottom coating layer BC1 may include silicon or a resin material having a good stretchability. For example, the first bottom coating layer BC1 may include at least one selected from urethane-based resin, epoxy based resin, polyester based resin, polyether based resin, acrylate based resin, acrylonitrile-butadien-styrene (ABS) resin, and rubber. Specifically, the first bottom coating layer BC1 may include at least one of phenylene, polyethyleneterephthalate (PET), polyimide, (PI), polyamide, (PAI), polyethylene naphthalate (PEN), and polycarbonate (PC).

The back plate BP may be disposed below the glass substrate GS. The back plate BP may be attached onto a rear surface of the glass substrate GS and the first bottom coating layer BC1 to further support the thin display panel DP and reduce the strain of the glass substrate GS during the folding operation, but may be excluded if necessary.

The back plate 150 may be formed of a polymer such as polyimide (PI), polymethylmetacrylate (PMMA), polycarbonate (PC), polyvinylalcohol (PVA), acrylonitrilebutadiene-styrene (ABS), polyethylene terephthalate (PET), silicone, or polyurethane (PU), but is not limited thereto.

A first adhesive layer ADH1 is disposed between the back plate BP and the first bottom coating layer BC1. The first adhesive layer ADH1 attaches the back plate BP and the first bottom coating layer BC1. The first adhesive layer ADH1 may be formed of a transparent adhesive member such as an optically clear resin (OCR) or an optically clear adhesive (OCA), but is not limited thereto. The first adhesive layer ADH1 may be omitted depending on whether to use the back plate BP.

The display panel DP is disposed on the glass substrate GS.

The display panel DP includes a flexible substrate, a driving thin film transistor, a display element, or the like. In the display panel DP, the flexible substrate on which the driving thin film transistor and the display element are formed may be encapsulated by an encapsulation unit. The display panel DP includes a flexible substrate with a small thickness and a display element disposed on the flexible substrate to implement the flexibility.

The display element may be defined in different ways depending on a type of the display panel DP. For example, when the display panel DP is an organic light emitting display panel DP, the display element may be an organic light emitting diode which includes an anode, an emission layer, and a cathode. Further, the display panel DP may be an inorganic light emitting display device in which the light emitting diode is implemented by a light emitting diode based on an inorganic material. For example, the display panel DP may be a quantum dot display panel DP in which the light emitting diode is implemented by a quantum dot which is a self-emitting semiconductor crystal. The display panel DP will be described in detail with reference to FIG. 3.

The cover glass CG is disposed on the display panel DP. The cover glass CG protects the display panel DP from the external shocks and scratches. Therefore, the cover glass CG may be formed of a material which is transparent and has excellent impact resistance and scratch resistance. Further, the cover glass CG protects the display panel DP from the moisture permeating from the outside. Therefore, the cover glass CG suppress the display panel DP from deteriorating to degrade the display quality.

A thickness of the cover glass CG may be 30 μm to 90 μm. The cover glass CG having such a thickness has an advantage of excellent folding characteristic. The cover glass CG may be a chemically strengthened glass. The chemically strengthened glass is a glass which is strengthened by a chemical strengthening method. The chemical strengthening method is a process of enhancing the strength of the glass by an ion exchange method which replaces sodium ions included in the glass with ions having an ion radius larger than that of the sodium ions. Ions having an ion radius larger than that of sodium ions which configure the glass are permeated so that a compressive stress layer is formed on the glass surface to enhance the strength. For example, the chemically strengthened glass may be prepared by a process of immersing glass in a potassium salt solution such as potassium nitride and substituting the sodium ions of the glass with potassium ions while heating at 200° C. to 450° C. for a predetermined time, but is not limited thereto. 200° C. to 450° C. is a temperature which is equal to or lower than a glass transition temperature.

A protection layer PL may be disposed on the cover glass CG. The protection layer PL protects the display panel DP from external shocks, scratches, or foreign materials and suppresses the scattering of the fragments when the cover glass CG is broken. The protection layer PL may be a protective film. For example, the protective film may be a plastic film including one or more selected from polyethylene terephthalate (PET), polyethylene naphthalate (PEN), polyethylene (PE), poly(methyl methacrylate) (PMMA), polyimide (PI), polyamide-imide (PAI), polycarbonate (PC), and cycloolefin (co) polymer, but is not limited thereto.

Further, the protection layer PL may be anti-scattering layer. The anti-scattering layer may serve as a buffer to suppress a damage of the cover glass CG from external shocks and suppress fragments from scattering when damage occurs. For example, the anti-scattering layer may include polyurethane or silicon-based resin, which absorbs shocks applied from the outside and suppresses the fragments from scattering when the cover glass CG is broken. The anti-scattering layer may be formed by coating a top surface of the cover glass CG with an anti-scattering coating agent.

A second adhesive layer ADH2 is disposed between the cover glass CG and the display panel DP. The second adhesive layer ADH2 attaches between the cover glass CG and the display panel DP. The second adhesive layer ADH2 may be formed of a transparent adhesive member such as an optically clear resin (OCR) or an optically clear adhesive (OCA), but is not limited thereto.

Hereinafter, a display panel DP of the present disclosure will be described in detail with reference to FIG. 3. FIG. 3 is a schematic cross-sectional view of a display panel of FIG. 2.

Referring to FIG. 3, the plurality of sub pixels SP may include a first sub pixel SP1, a second sub pixel SP2, and a third sub pixel SP3. The display panel DP of the foldable display device 100 according to the exemplary embodiment of the present disclosure includes a flexible substrate 110, a thin film transistor TFT, an organic light emitting diode 130, an encapsulation layer 140, a touch sensor unit 150, a plurality of color filters 170, a black matrix 180, and an over coating layer 190.

The flexible substrate 110 is a base member for supporting various components included in the display panel DP and may be formed of an insulating material. The flexible substrate 110 may be formed of an insulating material having a very small thickness to implement the flexibility. For example, the flexible substrate may be an insulating plastic substrate selected from polyimide, polyethersulfone, polyethylene terephthalate, and polycarbonate, but is not limited thereto. In the meantime, in the foldable display device 100 according to the exemplary embodiment of the present disclosure, the flexible substrate may be omitted. In this case, the other configurations of the display panel DP may be directly formed on the glass substrate GS located therebelow.

A first buffer layer 121 may be disposed on the flexible substrate 110 to suppress permeation of oxygen or moisture. The first buffer layer 121 may be formed as a single layer and may be formed with a multilayered structure if necessary.

On the first buffer layer 121, a thin film transistor TFT including a gate electrode G, an active layer ACT, a source electrode S, and a drain electrode D is disposed. The thin film transistor TFT is disposed in each area of the first sub pixel SP1, the second sup pixel SP2, and the third sub pixel SP3. In FIG. 3, only a driving thin film transistor, among various thin film transistors which may be included in the foldable display device 100, is illustrated for the convenience of description. Further, it is described that the thin film transistor TFT has a coplanar structure as an example in FIG. 3, but the present disclosure is not limited thereto and a thin film transistor TFT having an inverted staggered structure may also be used.

For example, the active layer ACT is disposed on the first buffer layer 121 and a gate insulating layer 123 is disposed on the active layer ACT to insulate the active layer ACT and the gate electrode G from each other. Further, an interlayer insulating layer 122 is disposed on the first buffer layer 121 to insulate the gate electrode G from the source electrode S and the drain electrode D. The source electrode S and the drain electrode D which are in contact with the active layer ACT are formed on the interlayer insulating layer 122. The planarization layer 124 may be disposed on the thin film transistor TFT. The planarization layer 124 planarizes an upper portion of the thin film transistor TFT. The planarization layer 124 may include a contact hole which electrically connects the thin film transistor TFT and the anode 131 of the organic light emitting diode 130.

The organic light emitting diode 130 is disposed on the planarization layer 124. For example, the organic light emitting diode 130 is formed in each of, a first sub pixel SP1, a second sub pixel SP2, and a third sub pixel SP3. Each of the organic light emitting diodes 130 includes an anode 131, an organic light emitting layer 132, and a cathode 133.

The anode 131 is disposed on the planarization layer 124. The anode 131 is disposed so as to correspond to each of the plurality of sub pixels SP1, SP2, and SP3. The anode 131 is formed of a conductive material having a high work function to supply holes to the organic light emitting layer 132. The anode 131 may be a transparent conductive layer which is formed of transparent conductive oxide (TCO). For example, the anode 131 may be formed by one or more selected from transparent conductive oxides such as indium tin oxide (ITO), indium zinc oxide (IZO), indium tin zinc oxide (ITZO), tin oxide (SnO₂), zinc oxide (ZnO), indium copper oxide (ICO), and aluminum: zinc oxide (Al: ZnO, AZO), but is not limited thereto. When the foldable display device 100 is driven as a top emission type, the anode 131 may further include a reflection layer which reflects light emitted from the light emitting layer 132 toward the cathode 133. The anode 131 may be separately formed for each of the first sub pixel SP1, the second sub pixel SP2, and the third sub pixel SP3.

A bank 125 is disposed on the anode 131 and the planarization layer 124. The bank 125 may cover an edge of the anode 131 of the organic light emitting diode 130 to define an emission area. That is, the bank 125 may divide the plurality of sub pixels SP1, SP2, and SP3. The bank 125 may be formed of an insulating material which insulates anodes 131 of adjacent sub pixels SP1, SP2, and SP3 from each other. Further, the bank 125 may be configured by a black bank having high light absorptance to suppress color mixture between adjacent sub pixels SP1, SP2, and SP3. For example, the bank 125 may be formed of a polyimide resin, an acrylic resin, or a benzocyclobutene resin, but is not limited thereto.

The cathode 133 is disposed on the anode 131. The cathode 133 may be formed of a metal material having a low work function to smoothly supply electrons to the organic light emitting layer 132. For example, the cathode 133 may be formed of a metal material selected from calcium (Ca), barium (Ba), aluminum (Al), silver (Ag), and alloys including one or more of them, but is not limited thereto. Referring to FIG. 3, the cathode is formed on the anode 131 as one layer. That is, the cathode 133 may be formed in the first sub pixel SP1, the second sub pixel SP2, and the third sub pixel SP3 as a single layer. When the foldable display device 100 is driven as a top emission type, the cathode 133 may be formed to have a very small thickness to be substantially transparent.

The organic light emitting layer 131 is disposed between the anode 131 and the cathode 133. The organic light emitting layer 132 is a layer in which electrons and holes are coupled to emit light. An organic light emitting layer of the first sub pixel SP1 is a red organic light emitting layer, an organic light emitting layer of the second sub pixel SP2 is a green organic light emitting layer, and an organic light emitting layer of the third sub pixel SP3 is a blue organic light emitting layer.

In order to improve luminous efficiency of the organic light emitting diode 130, a hole injection layer, a hole transport layer, an electron transport layer, and an electron injection layer may be further included. For example, the hole injection layer and the hole transport layer may be disposed between the anode 131 and the organic light emitting layer 132 and the electron transport layer and the electron injection layer may be disposed between the organic light emitting layer 132 and the cathode 133. Further, a hole blocking layer or an electron blocking layer may be disposed to further improve a recombination efficiency of the holes and electrons in the organic light emitting layer 132.

The encapsulation layer 140 is disposed on the organic light emitting diode 130. The encapsulation layer 140 may cover the organic light emitting diode 130. The encapsulation layer 140 may protect the organic light emitting diode 130 from moisture, oxygen, and impacts of the outside. The encapsulation layer 140 may be formed with a multilayered structure in which an inorganic layer formed of an inorganic insulating material and an organic layer formed of an organic material are laminated. For example, the encapsulation layer 140 may be configured by at least one organic layer and at least two inorganic layers and have a multilayered structure in which the inorganic layers and the organic layer are alternately laminated, but is not limited thereto. For example, the encapsulation layer 140 may have a triple layered structure including a first inorganic layer 141, an organic layer 142, and a second inorganic layer 143. In this case, the first inorganic layer 141 and the second inorganic layer 143 may be independently formed of one or more selected from silicon nitride (SiNx), silicon oxide (SiOx), aluminum oxide (AlOx), and silicon oxynitride (SiON), but is not limited thereto. Further, the organic layer 142 may be formed of one or more selected from epoxy resin, polyimide, polyethylene, and silicon oxycarbide (SiOC), but is not limited thereto.

A touch sensor unit 150 is disposed on the encapsulation layer 140 to impart a touch sensing function to the foldable display device 100. The foldable display device 100 according to the exemplary embodiment of the present disclosure includes a touch sensor unit 150 with a structure in which the touch electrode 151 is formed on the encapsulation layer 140, rather than a structure in which a touch panel of the related art in which a touch electrode is formed on a separate base member is disposed above the organic light emitting diode by means of the adhesive member. As the touch sensor unit 150 is directly formed on the encapsulation layer 140, the adhesive member which attaches the touch sensor unit 150 and the organic light emitting display panel DP is omitted so that the thickness of the foldable display device 100 may be reduced.

The touch sensor unit 150 includes a touch electrode 151 and a touch protection layer 152. The touch electrode 151 may be directly formed on the encapsulation layer 140 without using an adhesive member. The touch electrode 151 is an electrode which senses a touch input and may be configured by a sensing electrode and a driving electrode and may detect a touch coordinate by sensing a change of the capacitance between the sensing electrode and the driving electrode. For example, the driving electrode is disposed on the second inorganic layer 143 and the sensing electrode may be disposed on the same planar surface as the driving electrode. As another example, a touch insulating layer is disposed on the driving electrode and the sensing electrode may be disposed on the touch insulating layer. The placement of the touch electrode 151 is not limited thereto and may vary as needed.

The touch electrode 151 is directly formed on the encapsulation layer 140 so that a distance between the organic light emitting diode 130 and the touch electrode 151 is too close so that a parasitic capacitance is generated between the electrode included in the organic light emitting diode 130 or the thin film transistor TFT and the touch electrode 151. Therefore, the touch sensitivity may be degraded. Therefore, the thickness of the encapsulation layer 140 may be appropriately adjusted to minimize the parasitic capacitance.

The touch electrode 151 may be formed of a transparent metal material which transmits the light, such as indium tin oxide (ITO) or indium zinc oxide (IZO). The touch electrode 151 may have various shapes such as a rectangular shape, an octagonal shape, a circular shape, or a rhombus shape.

A touch protection layer 152 is disposed on the touch electrode 151. The touch protection layer 152 suppresses the short-circuit or damage of the touch electrode 151 and planarizes an upper surface of the touch electrode 151. The touch protection layer 152 may be formed of a transparent insulating resin such as an acrylic-based resin, a polyester-based resin, an epoxy resin, or a silicon-based resin.

In the meantime, in FIG. 3, a structure in which the touch electrode 151 of the touch sensor unit 150 is in direct contact onto the encapsulation layer 140 has been disclosed, but it is not limited thereto. For example, the touch buffer layer is disposed between the encapsulation layer 140 and the touch sensor unit 150 and the touch electrode 151 may be disposed on the touch buffer layer. The touch buffer layer may suppress the damage of the encapsulation layer 140 and the organic light emitting diode 130 during a process of directly forming the touch electrode 151 on the encapsulation layer 140.

The touch buffer layer may be formed of an inorganic material having an excellent barrier property. Therefore, the permeation of moisture or oxygen may be minimized. For example, the touch buffer layer may be formed of an inorganic material such as silicon nitride (SiNx), silicon oxide (SiOx), or aluminum oxide (AlOx), but is not limited thereto.

A second buffer layer 160 is disposed on the touch sensor unit 150. The second buffer layer 160 suppresses the permeation of the moisture or oxygen from the outside to protect the components of the foldable display device 100. The second buffer layer1 60 may be formed of an inorganic material having an excellent barrier property. Therefore, the permeation of moisture or oxygen may be minimized. For example, the second buffer layer 160 may be formed of one or more inorganic materials selected from silicon nitride (SiNx), silicon oxide (SiOx), silicon oxy nitride (SiON), and aluminum oxide (Al₂O₃), but is not limited thereto. Further, the second buffer layer 160 may compensate for deterioration of an adhesiveness between the plurality of color filters 170 and the black matrix 180 and the touch protection layer 152. That is, the second buffer layer 160 is disposed on the touch protection layer 152 to bond the plurality of color filters 170 and the black matrix 180 and the touch protection layer 152 to each other. The second buffer layer 160 may be omitted when the touch sensor unit 150 is disposed above the encapsulation layer 140 by means of the adhesive member or is disposed below the encapsulation layer 140. The plurality of color filters 170 and the black matrix 180 are disposed on the second buffer layer 160. The plurality of color filters 170 and the black matrix 180 are integrally formed on the same planar surface and absorb external light to minimize degradation of the visibility and a contrast ratio of the foldable display device 100 due to the external light.

The plurality of color filters 170 and the black matrix 180 are disposed on the second buffer layer 160. The plurality of color filters 170 and the black matrix 180 may serve as an anti-reflection layer which absorb external light to minimize the degradation of visibility and a contrast ratio of the foldable display device 100 due to the external light.

The black matrix 180 may be disposed on the touch sensor unit 150 or the second buffer layer 160. The black matrix 180 is disposed along a boundary of the sub pixels and includes an opening which opens the sub pixel. The black matrix 180 divides each of the plurality of color filters 170. The black matrix 180 may be disposed so as to overlap the bank 125. Therefore, the color mixture between the sub pixels SP1, SP2, and SP3 may be minimized. Further, the black matrix 180 absorbs external light. Therefore, the degradation of the visibility and the contrast ratio of the foldable display device 100 due to the external light may be minimized.

The plurality of color filters 170 is disposed on the encapsulation layer 140. The plurality of color filters 170 may be disposed on the touch sensor unit 150 or the second buffer layer 160. Further, the plurality of color filters 170 is disposed to be in direct contact with the second buffer layer 160 and may be disposed to cover a partial area of the black matrix 180. The plurality of color filters 170 absorbs external light to minimize degradation of the visibility and the contrast ratio due to the external light and improve a color reproductivity. The plurality of color filters 170 is disposed on the encapsulation layer 140 to improve the luminous efficiency and omit a polarizer or a polarization film.

The plurality of color filters 170 is disposed so as to correspond to a sub pixel disposed therebelow. At this time, referring to FIG. 3, the plurality of color filters 170 includes a first color filter 171 corresponding to the first sub pixel SP1, a second color filter 172 corresponding to the second sub pixel SP2, and a third color filter 173 corresponding to the third sub pixel SP3. When the first sub pixel SP1 is a red sub pixel, the first color filter 171 is a red color filter. Further, when the second sub pixel SP2 is a green sub pixel, the second color filter 172 is a green color filter and when the third sub pixel SP3 is a blue sub pixel, the third color filter 173 is a blue color filter.

As each color filter 170 is disposed so as to correspond to the color of each corresponding sub pixel SP1, SP2, SP3, internal light emitted from each of the first sub pixel SP1, the second sub pixel SP2, and the third sub pixel SP3 passes through the color filter 170. For example, red light emitted from the first sub pixel SP1 passes through the first color filter 171. In contrast, when external light is incident, external light corresponding to an absorption wavelength of a coloring material included in each color filter 170 is absorbed by the color filter 170. External light which is not absorbed by the color filter 170 is reflected from the cathode 133 to pass through the color filter 170 again. Reflected light corresponding to the absorption wavelength of the coloring material included in each color filter 170 is absorbed by the color filter 170. Therefore, the degradation of the display quality due to the external light may be minimized.

An over coating layer 190 is disposed so as to cover the plurality of color filters 170 and the black matrix 180. The over coating layer 190 may planarize upper portions of the plurality of color filters 170 and the black matrix 180. For example, the over coating layer 190 may be formed of transparent resin, such as acrylic based resin, silicon-based resin, polyester based resin, and epoxy resin, but is not limited thereto.

In the meantime, the over coating layer 190 may include an UV absorbing layer. The UV absorbing layer blocks light with ultraviolet wavelength from external light incident to the foldable display device 100. The UV absorbing layer blocks light with a wavelength which is equal to or lower than 400 nm and transmits visible ray with a wavelength which exceeds approximately 400 nm. The UV absorbing layer may be formed of an organic material including an UV blocker or an UV absorber which blocks or absorbs light with a wavelength which is equal to or lower than 400 nm. The UV blocker or UV absorber may be used without limitation as long as the UV blocker or UV absorber is a material used in this technical field.

Referring to FIG. 2, the over coating layer 190 includes a plurality of second patterns P2 so as to correspond to the folding shoulder area SA of the folding area FA of the foldable display device 100. The plurality of second patterns P2 reduces a folding stress which is applied to the over coating layer 190 during the folding operation and improves the adhesiveness between the over coating layer 190 and the second adhesive layer to suppress the peeling and crack generated on the over coating layer 190.

The second pattern P2 may be an opening pattern or a hole which is formed by penetrating the over coating layer 190 in the thickness direction. When the foldable display device 100 is folded, the stress is concentrated on the folding area FA. The second pattern P2 may disperse the stress concentrated on the folding area FA of the over coating layer 190 during the folding.

Each of the plurality of second patterns P2 may be formed to extend long in a direction parallel to the folding axis (X-axis direction in FIG. 1). That is, the second pattern P2 may be formed to extend long along the same direction as the folding axis. Therefore, the second pattern P2 may be formed to be parallel to the folding axis in the form of bar in the plan view.

In the meantime, in FIG. 2, a structure in which the plurality of second patterns P2 is formed in the folding area FA with the same shape and interval has been illustrated, but the present disclosure is not limited thereto. That is, the second patterns P2 may be formed in the folding center area CA and the folding shoulder area SA with different thicknesses, widths, and intervals. Further, the plurality of second patterns P2 may be formed in the entire folding area FA or may also be formed only a partial area of the folding area FA. That is, the plurality of second patterns P2 may be formed only in a partial area of the folding center area CA and the folding shoulder area SA.

In the meantime, the plurality of second patterns P2 may have a shape corresponding to the first pattern P1 of the glass substrate GS. Referring to FIG. 2, the plurality of second patterns P2 may be disposed so as to overlap the first pattern P1 of the glass substrate GS. However, the present disclosure is not limited thereto and the plurality of second patterns P2 may be formed to have an opposite shape to the plurality of first patterns P1 of the glass substrate GS. For example, the plurality of second patterns P2 of the over coating layer 190 has an opening shape and the plurality of first patterns P1 of the glass substrate GS has a groove or a concave portion. At this time, the opening area of the over coating layer 190 may correspond to the concave portion of the glass substrate GS in a vertical direction (Z-axis direction).

The foldable display device according to the exemplary embodiment of the present disclosure may reduce a folding stress which is applied to the foldable display device 100 by means of the plurality of first patterns P1 formed on the glass substrate GS and the plurality of second patterns P2 formed on the over coating layer 190. Further, a plurality of plates which is used to ensure the folding performance and the rigidity in the foldable display device of the related art is not used, but the mother substrate or the carrier substrate is used as a base substrate as it is to ensure the number of processes and the economic feasibility. Specifically, when the glass substrate GS and the cover glass CG are used, both the restricted foldability and durability are satisfied.

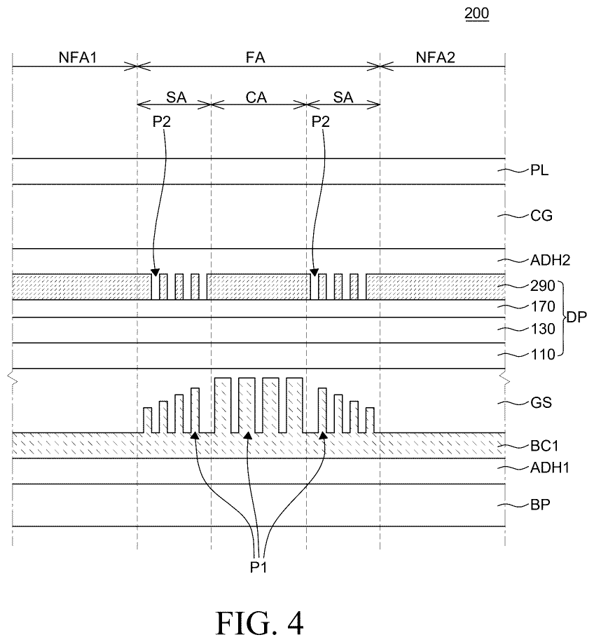

FIG. 4 is a schematic cross-sectional view of a foldable display device according to another exemplary embodiment of the present disclosure. A foldable display device 200 illustrated in FIG. 4 has the substantially same configurations as the foldable display device 100 illustrated in FIGS. 1 to 3 except shapes of a first pattern P1 formed on the glass substrate GS and a second pattern P2 formed on the over coating layer 290. Therefore, a redundant description will be omitted.

Referring to FIG. 4, the first pattern P1 formed on the glass substrate GS may be formed in the folding center area CA and the folding shoulder area SA with different thicknesses, widths, and intervals. Referring to FIG. 4, a thickness of the first pattern P1 located in the folding shoulder area SA is smaller than a thickness of the first pattern P1 in the folding center area CA. During the folding operation, the glass substrate GS is subjected to strong compressive stress in the folding shoulder area SA to cause cracks and peeling. Therefore, the thickness of the first pattern P1 located in the folding shoulder area SA is formed to be smaller than the thickness of the first pattern P1 in the folding center area CA to improve the durability against the compressive stress while maintaining the foldability. In the meantime, the more adjacent to the non-folding areas NFA1 and NFA2, the gradually smaller the thickness of the first pattern P1 in the folding shoulder area SA.

Further, a width of the first pattern P1 located in the folding shoulder area SA and an interval between the first patterns P1 may be smaller than a width of the first pattern P1 located and an interval between the first patterns P1 in the folding center area CA. As described above, the glass substrate GS in the folding shoulder area SA is applied with a strong compressive stress during the folding operation so that the width and the intervals of the first pattern P1 located in the folding shoulder area SA are set to be denser. Therefore, the folding stress of the glass substrate GS applied in the folding shoulder area SA is reduced and the durability may be improved. In the meantime, the more adjacent to the non-folding areas NFA1 and NFA2, the gradually smaller the width and the interval of the first patterns P1 in the folding shoulder area SA so that a denser pattern may be formed.

Next, in the foldable display device 100 illustrated in FIG. 2, the second pattern P2 formed in the over coating layer 190 is formed in the entire folding area FA. In contrast, in the foldable display device 200 illustrated in FIG. 4, the second pattern P2 may be formed only in the folding shoulder area SA. As described above, the components of the foldable display device 200 are applied with specifically strong compressive stress in the folding shoulder area SA during the folding operation. Also in the over coating layer 290, the compressive stress is concentrated in the folding shoulder area SA. The second pattern P2 may disperse the stress concentrated in the folding shoulder area FA of the over coating layer 290 during the folding.

The plurality of second patterns P2 may have a shape which is disposed to be alternate with the first patterns P1 of the glass substrate GS. Specifically, the plurality of second patterns P2 of the over coating layer 290 may be formed to have an opposite shape to the plurality of first patterns P1 of the glass substrate GS. Referring to FIG. 4, the plurality of second patterns P2 of the over coating layer has an opening shape and the plurality of first patterns P1 of the glass substrate GS has a groove or a concave portion. At this time, the opening area of the over coating layer 290 may correspond to the convex portion of the glass substrate GS in a vertical direction (Z-axis direction). In other words, a portion of the over coating layer 290 which remains without being open by the second pattern P2 may correspond to the groove or the concave portion of the glass substrate GS formed by the first pattern P1. Like the foldable display device 200 illustrated in FIG. 4, when the first pattern P1 of the glass substrate GS and the second pattern P2 of the over coating layer 290 are alternately disposed, during the folding, the stress is reduced and the flatness of the entire display panel is improved by the complementary structure between the first pattern P1 and the second pattern P2. By doing this, the durability may be improved.

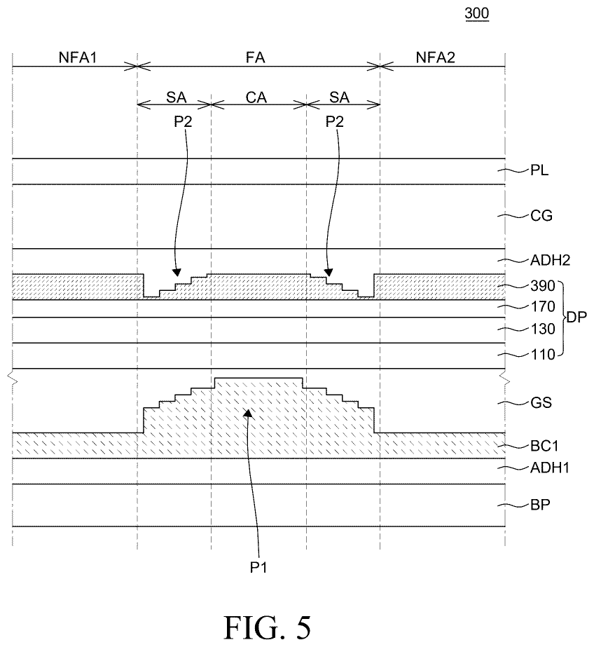

FIG. 5 is a schematic cross-sectional view of a foldable display device according to still another exemplary embodiment of the present disclosure. A foldable display device 300 illustrated in FIG. 5 has the substantially same configurations as the foldable display device 200 illustrated in FIG. 4 except shapes of a first pattern P1 formed on the glass substrate GS and a second pattern P2 formed on the over coating layer 390. Therefore, a redundant description will be omitted.

Referring to FIG. 5, the first pattern P1 formed on the glass substrate GS may form one groove over the entire folding area FA. Specifically, the first pattern P1 may be a groove with a concave shape from an outer surface to the inner surface of the glass substrate GS. The first pattern P1 may be formed with a stepped shape which is gradually deepened from an area adjacent to the non-folding areas NFA1 and NFA2 toward the center of the folding area FA. That is, the first pattern P1 forms a step in the folding area FA and the more adjacent to the folding center area CA, the gradually larger the depth of the groove of the first pattern P1 in the folding shoulder area SA.

In the meantime, the second pattern P2 formed in the over coating layer 390 may also form one groove over the entire folding area FA. The second pattern P2 may be a groove which is concave from the top surface to the bottom surface of the over coating layer 390. The second pattern P2 may have an opposite shape to the first pattern P1. That is, the second pattern P2 may be formed with a stepped shape which is gradually shallower from an area adjacent to the non-folding areas NFA1 and NFA2 toward the center of the folding area FA. The second pattern P2 forms a step in the folding area FA and the more adjacent to the folding center area CA, the gradually smaller the depth of the groove of the second pattern P2 in the folding shoulder area SA. That is, the second pattern P2 has a stepped shape which is deepened toward the non-folding areas NFA1 and NFA2.

At this time, the stepped shape of the first pattern P1 formed in the glass substrate GS may correspond to the stepped shape of the second pattern P2 formed in the over coating layer 390. That is, even though the depths of the patterns are different, the step portion formed by the first pattern P1 may coincide with a step of the over coating layer formed by the second pattern in a vertical direction (Z-axis direction).

In the foldable display device 300 illustrated in FIG. 5, the first pattern P1 formed in the glass substrate GS has one groove shape which has a stepped shape over the entire folding area FA so that the glass substrate GS may be more easily folded. However, there may be a possibility that the durability of the glass substrate GS may be degraded due to the first pattern P1. Therefore, the second pattern P2 formed in the over coating layer 390 is formed to have a stepped shape having an opposite intaglio to the first pattern P1 to compensate for the glass substrate GS etched by the first pattern P1. Therefore, the durability may be improved.

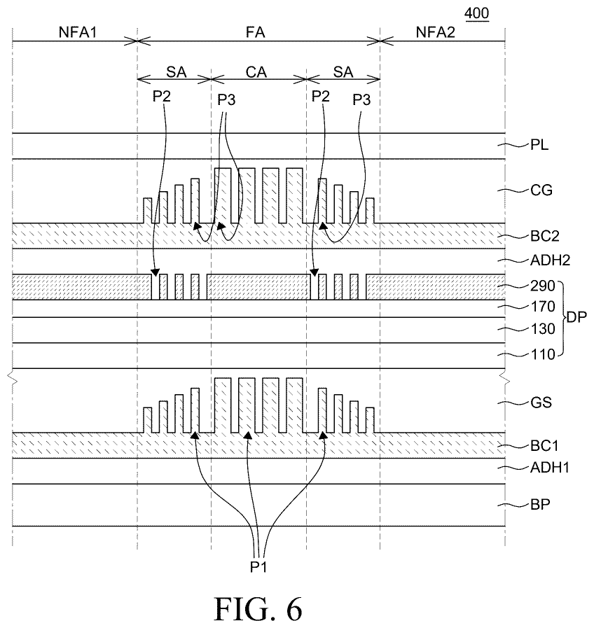

FIG. 6 is a schematic cross-sectional view of a foldable display device according to still another exemplary embodiment of the present disclosure. A foldable display device 400 illustrated in FIG. 6 has the substantially same configurations as the foldable display device 200 illustrated in FIG. 4 except that a third pattern P3 is formed on the cover glass CG and a second bottom coating layer BC2 is formed below the cover glass CG. Therefore, a redundant description will be omitted.

Referring to FIG. 6, the third pattern P3 is formed on the cover glass CG. The third pattern P3 may be a concave pattern or a groove which is formed from the bottom surface to the top surface to allow the foldable display device 400 to be inwardly folded. The third pattern P3 may have a structure in which concave portions and convex portions continuously and alternately disposed. Accordingly, the third pattern P3 may give a flexibility to the cover glass CG.

The plurality of third patterns P3 may disperse the stress concentrated on the folding area FA during the folding. As described above, as the plurality of third patterns P3 is formed in a position corresponding to the folding area FA, it is advantageous in that the foldable display device 400 is easily folded and has an excellent resilience.

In the meantime, the third pattern P3 may have the same shape as the first pattern P1 of the glass substrate GS. Accordingly, the same description as the first pattern P1 is omitted. In the meantime, the third pattern P3 may be formed to substantially correspond to the first pattern P1.

In the meantime, the second bottom coating layer BC2 is disposed below the cover glass CG. The second bottom coating layer BC2 suppresses a shock applied from the outside from being transmitted to the display panel DP and suppresses the crack of the cover glass CG. Specifically, the second bottom coating layer BC2 is filled in the third pattern P3 formed on the cover glass CG and absorbs a folding stress generated on the cover glass CG during the in-folding operation, and may improve the foldability. Accordingly, a combination of the cover glass CG including the third pattern P3 and the second bottom coating layer BC2 allows the foldable display device 400 to be easily bent and reinforces the rigidity to reduce a strain of the cover glass CG.

A material which configures the second bottom coating layer BC2 is the substantially same as a material which configures the first bottom coating layer BC1, so that a redundant description will be omitted.

The foldable display device 400 illustrated in FIG. 6 forms a plurality of third patterns P3 with a concave shape not only on the glass substrate GS, but also on the cover glass CG to further improve the foldability of the foldable display device 100.

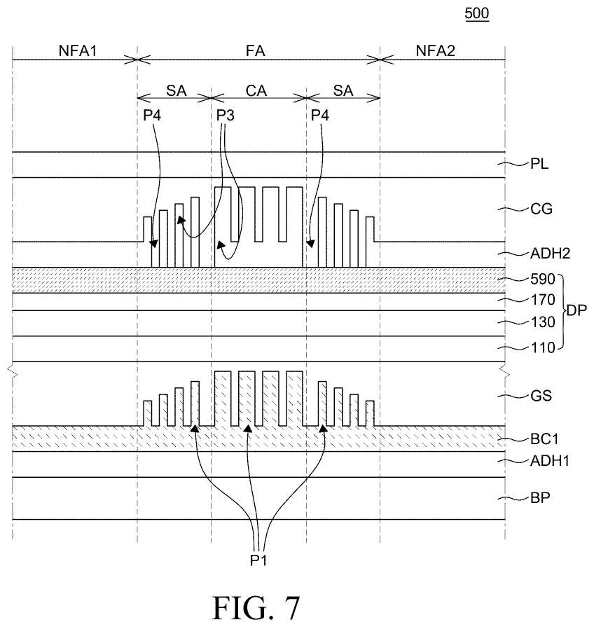

FIG. 7 is a schematic cross-sectional view of a foldable display device according to still another exemplary embodiment of the present disclosure. A foldable display device 500 illustrated in FIG. 7 has the substantially same configuration as the foldable display device 400 illustrated in FIG. 6 except that the second bottom coating layer BC2 is not disposed and structures of the cover glass CG and the second adhesive layer ADH2 are changed. Therefore, a redundant description will be omitted.

Referring to FIG. 7, the cover glass CG includes the third pattern P3. At this time, a shape of the third pattern P3 located in the folding center area CA is the same as a shape of the third pattern of the foldable display device 400 illustrated in FIG. 6. That is, the third pattern P3 located in the folding center area CA may be a concave pattern or a groove which is formed from the bottom surface to the top surface of the cover glass CG, as compared with the adjacent non-folding areas NFA1 and NFA2. However, the third pattern P3 located in the folding shoulder area SA has a concave portion which is formed from the bottom surface to the top surface of the cover glass CG and a convex portion which protrudes from the bottom surface of the cover glass CG toward the display panel DP. The convex portion may be inserted into the second adhesive layer ADH2 located therebelow.

The second adhesive layer ADH2 is disposed between the cover glass CG and the display panel DP. At this time, the second adhesive layer ADH2 may be filled in the third pattern P3 of the cover glass CG. That is, the second adhesive layer ADH2 may be filled in the concave portion of the cover glass CG formed by the third pattern P3. In the meantime, as described above, the convex portion formed by the third pattern P3 has a shape which protrudes from the cover glass CG toward the display panel to be inserted into the second adhesive layer ADH2. The second adhesive layer ADH2 may have a pattern shape by the convex portion of the cover glass CG which extends to the second adhesive layer ADH2.

The foldable display device 500 illustrated in FIG. 7 includes the concave portion and the convex portion formed by the third pattern P3 of the cover glass CG and the second adhesive layer ADH2 disposed below the cover glass CG is filled in the concave portion of the cover glass CG. Therefore, the second bottom coating layer may be omitted. By doing this, the number of processes of the foldable display device 400 is reduced and a thickness thereof may be reduced. Further, an additional pattern is formed in the second adhesive layer ADH2 below which the convex portion of the cover glass CG is located, so that the second pattern formed in the over coating layer in the foldable display device 400 illustrated in FIG. 6 may be replaced. By doing this, a separate process for forming the second pattern on the over coating layer 590 may be omitted so that the number of manufacturing processes of the foldable display device 500 may be reduced.

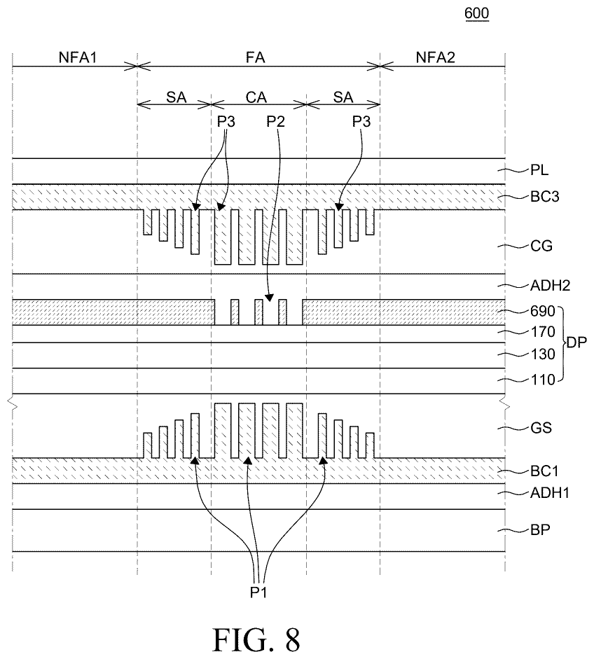

FIG. 8 is a schematic cross-sectional view of a foldable display device according to still another exemplary embodiment of the present disclosure. A foldable display device 500 illustrated in FIG. 8 has the substantially same configurations as the foldable display device 400 illustrated in FIG. 6 except that a second pattern P2 formed on the over coating layer 690 and a third pattern P3 formed on the cover glass CG have different shapes and a top coating layer BC3 is disposed instead of the second bottom coating layer. Therefore, a redundant description will be omitted.

Referring to FIG. 8, the third pattern P3 is formed on the cover glass CG. The third pattern P3 may be a concave pattern or a groove which is formed from the top surface of the cover glass CG toward the display panel DP to allow the foldable display device to be outwardly folded. The third pattern P3 may have a structure in which concave portions and convex portions continuously and alternately disposed. Accordingly, the third pattern P3 may give a flexibility to the cover glass CG.

The plurality of third patterns P3 may disperse the stress concentrated on the folding area FA when the foldable display device 600 is outwardly folded. During the out-folding operation of the foldable display device 600, unlike the in-folding, in both the cover glass CG and the over coating layer 690, a maximum compressive stress is applied to the folding center area CA. That is, when the foldable display device 600 is outwardly folded, largest tension is applied to the top surface of the cover glass CG located at the outside so that a groove is formed on the top surface of the cover glass CG to reduce the stress of the folding center area CA.

In the meantime, the third pattern P3 may have the same shape as the first pattern P1 of the glass substrate GS excluding the forming direction of the groove. Accordingly, the same description as the first pattern P1 is omitted. In the meantime, the third pattern P3 may be formed so as to substantially correspond to the first pattern P1. In the meantime, during the out-folding operation of the foldable display device 600, the ends of the pattern may be implemented to be rounded or sharply angled for the case that the patterns come into contact with each other depending on the radius of curvature.

In the meantime, the top coating layer BC3 is disposed above the cover glass CG. The top coating layer BC3 suppresses a shock applied from the outside from being transmitted to the display panel DP and suppresses the crack of the cover glass CG. Specifically, the top coating layer BC3 is filled in the third pattern P3 formed on the cover glass CG and absorbs a folding stress generated on the cover glass CG during the out-folding operation, and may improve the foldability. Accordingly, a combination of the cover glass CG including the third pattern P3 and the top coating layer BC3 allows the foldable display device 600 to be easily bent and reinforces the rigidity to reduce a strain of the cover glass CG.

Referring to FIG. 8, the over coating layer 690 includes a plurality of second patterns P2 to correspond to the folding center area SA. The plurality of second patterns P2 reduces a folding stress which is applied to the over coating layer 690 during the out-folding operation and improves the adhesiveness between the over coating layer 690 and the second adhesive layer ADH2 to suppress the peeling and crack generated on the over coating layer 690.

As described above, during the out-folding operation of the foldable display device 600, unlike the in-folding, the over coating layer 690 is located above a neutral plane to be applied with the maximum compressive stress in the folding center area CA. Accordingly, an opening pattern is formed in the folding center area CA, rather than the folding shoulder area SA so that the stress concentrated in the folding center area CA of the over coating layer 690 may be dispersed.

In the meantime, the plurality of second patterns P2 may have a shape corresponding to the first pattern P1 of the glass substrate GS and the third pattern P3 of the cover glass CG. Specifically, the plurality of second patterns P2 of the over coating layer 690 may be formed to have the same shape as the first pattern P1 and the third pattern P3. Referring to FIG. 8, the plurality of second patterns P2 of the over coating layer 690 has an opening shape and the plurality of first patterns P1 of the glass substrate GS and the plurality of third patterns P3 of the cover glass CG form grooves. At this time, the opening area of the over coating layer 690 corresponds to the grooves of the glass substrate GS and the cover glass CG in the vertical direction (Z-axis direction).

The foldable display device 600 illustrated in FIG. 8 changes the shapes of the third pattern P3 of the cover glass CG and the second pattern P2 of the over coating layer 690 to suppress the crack and peeling of the cover glass CG and the over coating layer 690 even during the out-folding operation.

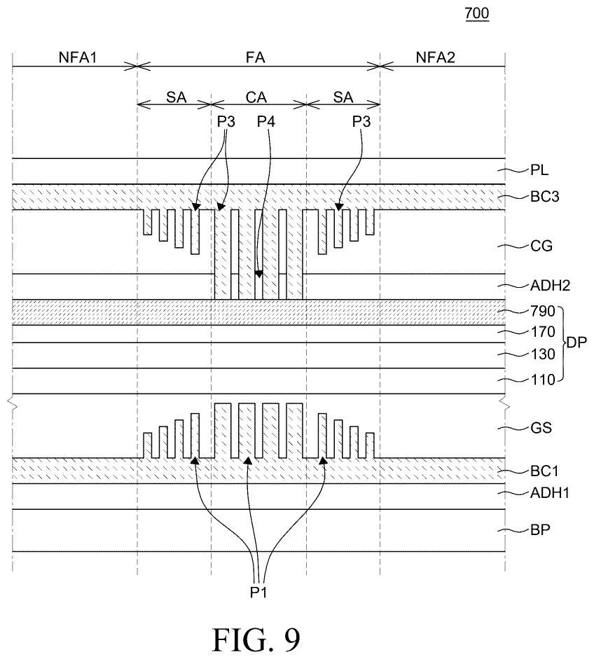

FIG. 9 is a schematic cross-sectional view of a foldable display device according to still another exemplary embodiment of the present disclosure. A foldable display device 700 illustrated in FIG. 9 has the substantially same configuration as the foldable display device 600 illustrated in FIG. 8 except that structures of a cover glass CG, a top coating layer BC3, an over coating layer 790, and the second adhesive layer ADH2 are changed. Therefore, a redundant description will be omitted.

Referring to FIG. 9, the cover glass CG includes the third pattern P3. At this time, a shape of the third pattern P3 located in the folding shoulder area SA is similar to a shape of the third pattern P3 of the foldable display device 600 illustrated in FIG. 8. For example, the third pattern P3 located in the folding shoulder area SA may be a concave pattern or a groove which is inwardly formed from the top surface of the cover glass CG toward the display panel DP. However, the shape of the third pattern P3 located in the folding center area CA may be an opening pattern or a hole which passes through the cover glass CG.

In the meantime, the second adhesive layer ADH2 disposed below the cover glass CG includes a fourth pattern P4. The fourth pattern P4 may be an opening pattern or a hole which passes through the second adhesive layer ADH2. A fourth pattern P4 of the second adhesive layer ADH2 may overlap the third pattern P3 of the cover glass CG to form one hole.

The top coating layer BC3 is disposed above the cover glass CG. The top coating layer BC3 suppresses a shock applied from the outside from being transmitted to the display panel DP and suppresses the crack of the cover glass CG. At this time, the top coating layer BC3 may be filled in both the third pattern P3 of the cover glass CG and the fourth pattern P4 of the second adhesive layer ADH2.

The foldable display device 700 illustrated in FIG. 9 forms a hole formed to overlap the cover glass CG and the second adhesive layer ADH2 to form the third pattern P3 and the fourth pattern P4. As compared with the foldable display device 600 illustrated in FIG. 8, the fourth pattern P4 formed on the second adhesive layer ADH2 may replace the second pattern formed on the over coating layer. Specifically, the third pattern P3 of the cover glass CG and the fourth pattern P4 of the second adhesive layer ADH2 may be simultaneously etched by one process to be formed before a process of bonding the display panel DP and the cover glass CG. That is, the third pattern P3 and the fourth pattern P4 are simultaneously formed so that a separate process for forming the second pattern on the over coating layer 790 is omitted so that the number of manufacturing processes of the foldable display device 600 may be reduced.

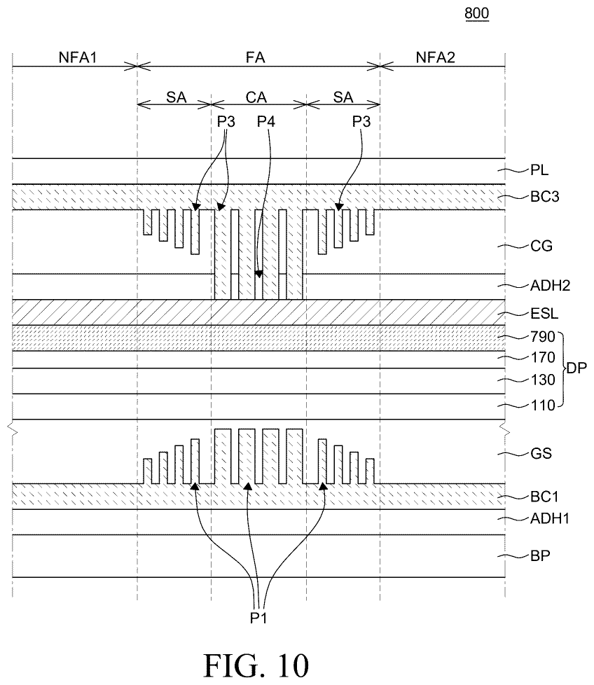

FIG. 10 is a schematic cross-sectional view of a foldable display device according to still another exemplary embodiment of the present disclosure. A foldable display device 800 illustrated in FIG. 10 has the substantially same configurations as the foldable display device 700 illustrated in FIG. 9 except that etch stop layers ESL is disposed below the second adhesive layer ADH2, so that a redundant description will be omitted.

Referring to FIG. 10, an etch stop layer ESL is disposed below the second adhesive layer ADH2. The etch stop layer ESL suppresses a damage generated by the etching process in a display panel DP disposed therebelow during the etching process of forming the third pattern on the cover glass CG and a fourth pattern on the second adhesive layer. The etch stop layer ESL may be formed of an inorganic material such as silicon oxide (SiO₂), but is not limited thereto.

The foldable display device 800 illustrated in FIG. 10 is an out-folding display device so that the foldable display device 800 includes the third pattern P3 which is a concave pattern or a groove inwardly formed from the top surface of the cover glass CG toward the display panel DP on the cover glass CG. According to the manufacturing process of the foldable display device 800, a thin film transistor TFT, an organic light emitting diode 130, a plurality of color filters 170, a black matrix 180, and an over coating layer 790 are sequentially formed on a mother substrate or a carrier substrate. Thereafter, the cover glass CG is directly coupled onto the over coating layer 790 using the second adhesive layer ADH2 and finally, the top surface of the cover glass CG is etched to reduce the thickness of the cover glass CG and form the third pattern P3 and the fourth pattern P4. However, during a process of forming a hole-shaped fourth pattern P4 which passes through the second adhesive layer ADH2, components located below the second adhesive layer ADH2, for example, the plurality of color filters 170 and the over coating layer 790 are also etched together or damaged. Accordingly, the etch stop layer ESL is formed on the over coating layer 790 to protect the display panel below the second adhesive layer ADH2 and improve process convenience.

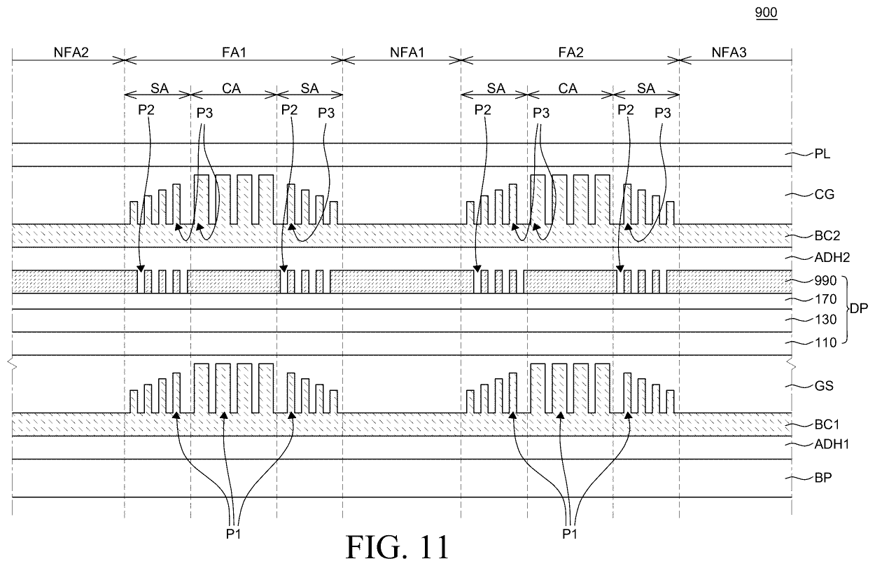

FIG. 11 is a schematic cross-sectional view of a foldable display device according to still another exemplary embodiment of the present disclosure. The foldable display device 900 illustrated in FIG. 11 may be a foldable display device 900 which includes a plurality of folding areas FA to enable the multi-folding by which the plurality of folding areas is simultaneously folded. The foldable display device 900 illustrated in FIG. 11 has the substantially same configuration as the foldable display device 400 illustrated in FIG. 6 except that a folding area FA includes a first folding area FA1 and a second folding area FA2, a first pattern P1 formed on the glass substrate GS, a second pattern P2 formed on the over coating layer 990, and a third pattern P3 formed on the cover glass CG are disposed in the first folding area FA1 and the second folding area FA2 to configure two sets. Therefore, a redundant description will be omitted.

Referring to FIG. 11, the foldable display device 900 includes a first non-folding area NFA1, a first folding area FA1, a second non-folding area NFA2, a second folding area FA2, and a third non-folding area NFA3 which are sequentially located along a folding direction (an X-axis direction). The foldable display device 900 of FIG. 11 may operate by an in-folding operation so that the display panel DP is folded or unfolded to be disposed inside in the first folding area FA1 and the second folding area FA2.

The glass substrate GS includes first patterns P1 formed in each of the first folding area FA1 and the second folding area FA2. The over coating layer 990 includes a second pattern P2 formed in each of the first folding area FA1 and the second folding area FA2 and the cover glass CG includes a third pattern P3 formed in the first folding area FA1 and the second folding area FA2. Description of the first pattern P1, the second pattern P2, and the third pattern P3 is the substantially same as that of the first pattern P1, the second pattern P2, and the third pattern P3 which have been described in FIG. 6. Therefore, a redundant description will be omitted. In the meantime, even though in FIG. 11, it is illustrated that the first pattern P1, the second pattern P2, and the third pattern P3 are the same as the first pattern P1, the second pattern P2, and the third pattern P3 formed in the foldable display device 400 illustrated in FIG. 6, the present disclosure is not limited thereto. That is, pattern shapes according to the exemplary embodiment described in the present disclosure, that is, the first pattern P1, the second pattern P2, and the third pattern P3 illustrated in FIGS. 2, 4, 6 to 10 are selectively applied to the foldable display device 900.

In the foldable display device 900 illustrated in FIG. 11, in each of the plurality of folding areas FA1 and FA2, the first pattern P1, the second pattern P2, and the third pattern P3 are formed in each of the glass substrate GS, the over coating layer 990, and the cover glass CG to improve the foldability and the durability. Specifically, a plurality of plates which is used to ensure the folding performance and the rigidity in the foldable display device of the related art is not used, but the mother substrate or the carrier substrate is used as a base substrate as it is to ensure the number of processes and the economic feasibility. Specifically, when the glass substrate GS and the cover glass CG are used, the restricted foldability may be also satisfied.

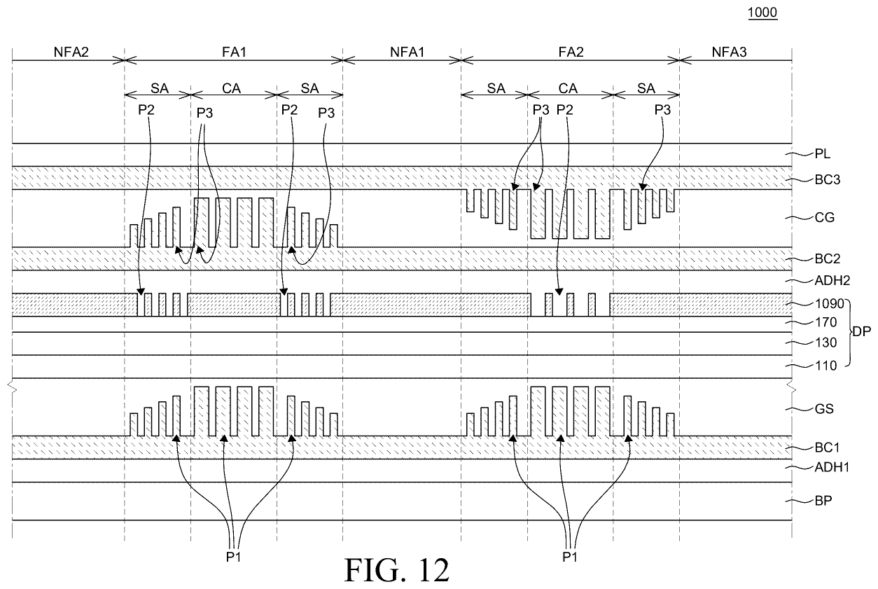

FIG. 12 is a schematic cross-sectional view of a foldable display device 1000 according to still another exemplary embodiment of the present disclosure. The foldable display device 1000 illustrated in FIG. 12 may be a foldable display device 1000 which includes a plurality of folding areas FA1 and FA2 to enable the multi-folding by which the plurality of folding areas is simultaneously folded. At this time, in the first folding area FA1, the foldable display device operates in an in-folding manner so that the display panel DP is folded or unfolded to be disposed inside. In the second folding area FA2, the foldable display device operates in an out-folding manner so that the display panel DP is folded or unfolded to be disposed outside.

In the foldable display device 1000 illustrated in FIG. 12, in a glass substrate GS, an over coating layer 1090, and a cover glass CG, different shapes of patterns are formed in the first folding area FA1 and the second folding area FA2.

Referring to FIG. 12, in the first folding area FA1, the glass substrate GS, the over coating layer 1090, and the cover glass CG form patterns which reduce a strong folding stress applied to the folding shoulder area SA during the in-folding and suppress peeling and cracks of the components. Specifically, in the first folding area FA1, the first pattern P1, the second pattern P2, and the third pattern P3 are formed as described above in FIG. 6. That is, the glass substrate GS includes the first pattern P1 having a groove shape formed from the bottom surface toward the display panel DP. Further, the over coating layer 1090 includes the second pattern P2 having a hole shape formed only in the folding shoulder area SA. Further, the cover glass CG includes the third pattern P3 having a groove shape formed from the bottom surface toward the display panel DP. At this time, a first bottom coating layer BC1 and a second bottom coating layer BC2 are disposed below the glass substrate GS and the cover glass CG to be filled in the first pattern P1 and the third pattern P3, respectively. With this configuration, when the first folding area FA1 operates in the inner folding manner, the folding stress applied to the first folding area FA1 is reduced and the durability of the display device may be improved.

Next, in the second folding area FA2, the glass substrate GS, the over coating layer 1090, and the cover glass CG form patterns which reduce a strong folding stress applied to the folding center area CA during the in-folding and suppress peeling and cracks of the components. Specifically, in the second folding area FA2, the first pattern P1, the second pattern P2, and the third pattern P3 as described above in FIG. 7 are formed. That is, the glass substrate GS includes the first pattern P1 having a groove shape formed from the bottom surface toward the display panel DP. Further, the over coating layer 1090 includes the second pattern P2 having a hole shape formed only in the folding center area CA. Further, the cover glass CG includes the third pattern P3 having a groove shape formed from the top surface toward the display panel DP. At this time, the first bottom coating layer BC1 is disposed below the glass substrate GS and the top coating layer BC3 is disposed above the cover glass CG. The first bottom coating layer BC1 and the top coating layer BC3 are filled in the first pattern P1 and the third pattern P3. With this configuration, when the second folding area FA2 operates in the out-folding manner, the folding stress applied to the second folding area FA2 is reduced and the durability of the display device may be improved.

The foldable display device 1000 illustrated in FIG. 12 may implement a foldable display device 1000 including a glass substrate GS with an improved foldability and durability by forming different patterns in the first folding area FA1 and the second folding area FA2 having different folding directions and radiuses of curvature to simultaneously implement the in-folding and the out-folding manners.

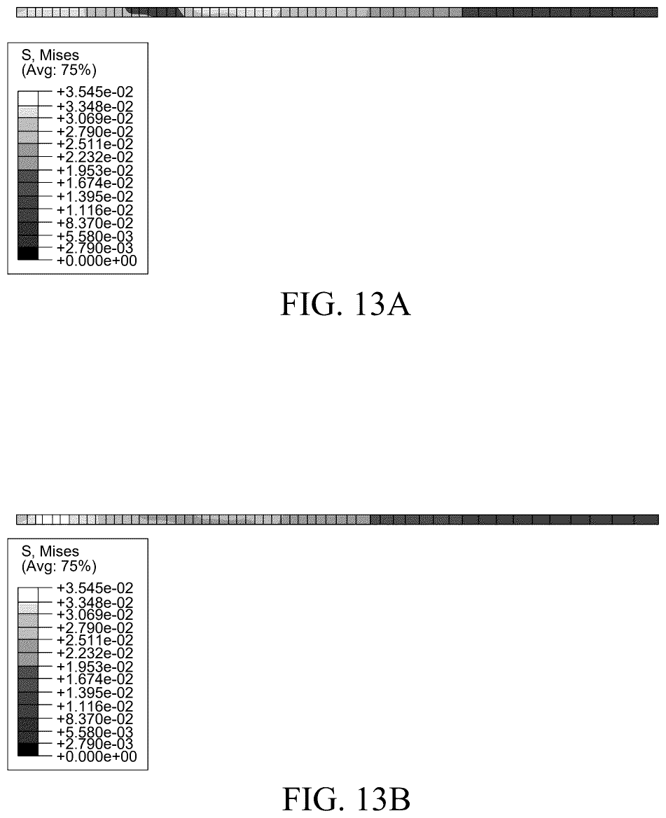

Hereinafter, a shear stress according to a position of the foldable display device according to the exemplary embodiment of the present disclosure and a foldable display device of Comparative Embodiment will be described with reference to FIGS. 13A to 13B.

FIG. 13A is a view illustrating a folding test simulation result of a foldable display device according to Embodiment 1. FIG. 13B is a view illustrating a folding test simulation result of a foldable display device of Comparative Embodiment 1.

In Embodiment 1, a foldable display device with a structure illustrated in FIG. 4 was prepared. In Embodiment 1, a bottom glass substrate GS with a thickness of 100 μm and a modulus of 73.3 GPa, a top cover glass CG with a thickness of 140 μm and a modulus of 73.3 GPa, an over coating layer 190 with a thickness of 3 μm and a modulus of 6.3 GPa, and a first bottom coating layer BC1 with a modulus of 300 MPa were formed. Also, the first pattern P1 of the bottom glass substrate GS and the second pattern P2 of the over coating layer 190 were formed with a width and an interval of 10 μm. In Comparative Embodiment 1, the same structure as Embodiment 1 except that the second pattern P2 was not formed on the over coating layer 190 was formed.

In FIGS. 13A and 13B, a simulation result obtained by calculating a strain stress which was applied to the display device when a folding area of the foldable display device according to Embodiment 1 and Comparative Embodiment 1 was pressed with a load of 0.2 kgf with a tip with a diameter of 2 mm was illustrated. At this time, all the simulations were analyzed using abaqus tool.

Comparing to FIGS. 13A and 13B, it was confirmed that the strain stress was locally significantly high in Comparative Embodiment 1. Further, when the first pattern of the glass substrate and the second pattern of the over coating layer were alternately disposed as in Embodiment 1, it was confirmed that as compared with Comparative Embodiment, an average strain stress was reduced by 7% or more.

The exemplary embodiments of the present disclosure can also be described as follows:

According to an aspect of the present disclosure, there is provided a foldable display device. The foldable display device including a folding area and non-folding areas located on both sides of the folding area, the folding area including folding shoulder areas located on both sides so as to be adjacent to the non-folding area and a folding center area located inside from the folding shoulder areas on both sides. The foldable display device includes a glass substrate including a first pattern provided so as to correspond to the folding area; a first bottom coating layer disposed on a bottom surface of the glass substrate and filled in the first pattern; a light emitting diode on the glass substrate; an encapsulation layer on the light emitting diode; a plurality of color filters and a black matrix on the encapsulation layer; and a cover glass on the plurality of color filters. Any one of organic material layers located between the plurality of color filters and the cover glass includes a second pattern which is provided so as to correspond to the folding area.

The first pattern may be formed by a groove which is formed from the bottom surface of the glass substrate toward a top surface.

The first pattern may be formed of a plurality of grooves and a plurality of grooves located in the folding shoulder area may have a smaller thickness or width or intervals than the plurality of grooves located in the folding center area.

The folding area may be inwardly folded such that a display surface of the foldable display device faces inward, the second pattern may be formed of a plurality of openings which passes through any one of the organic material layers, and the plurality of openings may be disposed in the folding shoulder area.

The plurality of grooves of the glass substrate in the folding shoulder areas may be disposed to be alternate with the plurality of openings.

The organic material layers may include an over coating layer on the plurality of color filters; and an adhesive layer on the over coating layer. The second pattern may be formed on the over coating layer.

The organic material layers may include an over coating layer disposed on the plurality of color filters, the second pattern may be formed of a groove which is formed from the top surface of the over coating layer toward the bottom surface of the over coating layer, the first pattern may have a stepped shape which is deepened toward the folding center area, and the second pattern may have a stepped shape which is deepened toward the non-folding area.

The cover glass may include a third pattern which is provided so as to correspond to the folding area and the third pattern may be formed by a plurality of grooves which is formed from a bottom surface of the cover glass toward a top surface.

The foldable display device may further comprise a second bottom coating layer which is disposed on a bottom surface of the cover glass and is filled in the third pattern. The third pattern may have the same shape as the first pattern.

The organic material layers may include an over coating layer on the plurality of color filters; and an adhesive layer on the over coating layer. The third pattern may include a plurality of concave portions formed from the bottom surface of the cover glass toward the top surface and a convex portion which protrudes toward the adhesive layer. The second pattern may be formed on the adhesive layer by the convex portion. And the adhesive layer may be filled in the third pattern.

The foldable display device may further comprise a top coating layer on the cover glass. The folding area may be outwardly folded such that a display surface of the foldable display device faces outside. The cover glass may include a third pattern which is provided so as to correspond to the folding area. The third pattern may be formed of a plurality of grooves which is formed from the top surface to the bottom surface of the cover glass. The top coating layer may be filled in the third pattern.

The organic material layers may include an over coating layer on the plurality of color filters; and an adhesive layer on the over coating layer. The second pattern may be formed by a plurality of openings which passes through the over coating layer so as to correspond to the folding center area.

The plurality of openings of the over coating layer may be located so as to overlap the plurality of grooves of the cover glass.

The organic material layers may include an over coating layer on the plurality of color filters; and an adhesive layer on the over coating layer. The second pattern may be formed of a plurality of openings which passes through the adhesive layer so as to correspond to the folding center area.

Each of the plurality of grooves of the cover glass located in the folding center area may be connected to each of the plurality of openings of the adhesive layer.

The foldable display device may further comprise an etch stop layer disposed between the over coating layer and the adhesive layer.

The folding area may include a first folding area which is inwardly folded such that a display surface of the foldable display device faces the inside and a second folding area which is outwardly folded such that the display surface of the foldable display device faces the outside. The first pattern may include a 1-1-th pattern provided so as to correspond to the first folding area and a 1-2-th pattern provided so as to correspond to the second folding area. The second pattern may include a 2-1-th pattern provided so as to correspond to the first folding area and a 2-2-th pattern provided so as to correspond to the second folding area. The 1-1-th pattern located in the first folding area may have the same shape as the 1-2-th pattern of the second folding area and the 2-1-th pattern located in the first folding area may have the different shape from the 2-2-th pattern of the second folding area.

The organic material layers may include an over coating layer on the plurality of color filters; and an adhesive layer on the over coating layer. The 2-1-th pattern may be formed of a plurality of 2-1-th openings which passes through the over coating layer so as to correspond to the folding shoulder area and the 2-2-th pattern may be formed of a plurality of 2-2-th openings which passes through the over coating layer so as to correspond to the folding center area.

The cover glass may include a 3-1-th pattern provided so as to correspond to the first folding area and a 3-2-th pattern provided so as to correspond to the second folding area, and the 3-1-th pattern located in the first folding area may have a different shape from the 3-2-th pattern located in the second folding area.

The 3-1-th pattern may be formed by a plurality of 3-1-th grooves which is formed from the bottom surface of the cover glass toward the top surface of the cover glass and the 3-2-th pattern may be formed by a plurality of 3-2-th grooves which is formed from the top surface of the cover glass toward the bottom surface of the cover glass.

It will be apparent to those skilled in the art that various modifications and variations can be made in the foldable display device of the present disclosure without departing from the technical idea or scope of the disclosure. Thus, it is intended that the present disclosure cover the modifications and variations of this disclosure provided they come within the scope of the appended claims and their equivalents.

What is claimed is:

1. A foldable display device including a folding area and non-folding areas located on both sides of the folding area, the folding area including folding shoulder areas located on both sides so as to be adjacent to the non-folding area and a folding center area located inside from the folding shoulder areas on both sides, the foldable display device comprising:
a glass substrate including a first pattern provided so as to correspond to the folding area;
a first bottom coating layer disposed on a bottom surface of the glass substrate and filled in the first pattern;
a light emitting diode on the glass substrate;
an encapsulation layer on the light emitting diode;
a plurality of color filters and a black matrix on the encapsulation layer; and
a cover glass on the plurality of color filters,
wherein any one of organic material layers located between the plurality of color filters and the cover glass includes a second pattern which is provided so as to correspond to the folding area.

2. The foldable display device according to claim 1, wherein the first pattern is formed by a groove which is formed from the bottom surface of the glass substrate toward the top surface of the glass substrate.

3. The foldable display device according to claim 2, wherein the first pattern is formed of a plurality of grooves and a plurality of grooves located in the folding shoulder area has a smaller thickness or width or intervals than the plurality of grooves located in the folding center area.

4. The foldable display device according to claim 2, wherein the folding area is inwardly folded such that a display surface of the foldable display device faces inward, the second pattern is formed of a plurality of openings which passes through any one of the organic material layers, and the plurality of openings is disposed in the folding shoulder area.

5. The foldable display device according to claim 4, wherein the plurality of grooves of the glass substrate in the folding shoulder areas is disposed to be alternate with the plurality of openings.

6. The foldable display device according to claim 5, wherein the organic material layers:
includes an over coating layer on the plurality of color filters; and
an adhesive layer on the over coating layer, and
the second pattern is formed on the over coating layer.

7. The foldable display device according to claim 2, wherein the organic material layers include an over coating layer disposed on the plurality of color filter,
the second pattern is formed of a groove which is formed from the top surface of the over coating layer toward the bottom surface of the over coating layer,
the first pattern has a stepped shape which is deepened toward the folding center area, and
the second pattern has a stepped shape which is deepened toward the non-folding area.

8. The foldable display device according to claim 1, wherein the cover glass includes a third pattern which is provided so as to correspond to the folding area and
the third pattern is formed by a plurality of grooves which is formed from a bottom surface of the cover glass toward a top surface.

9. The foldable display device according to claim 8, further comprising:
a second bottom coating layer which is disposed on a bottom surface of the cover glass and is filled in the third pattern,
wherein the third pattern has the same shape as the first pattern.

10. The foldable display device according to claim 9, wherein the organic material layers include:
an over coating layer on the plurality of color filters; and
an adhesive layer on the over coating layer, and
the third pattern includes a plurality of concave portions formed from the bottom surface of the cover glass toward the top surface and a convex portion which protrudes toward the adhesive layer,
the second pattern is formed on the adhesive layer by the convex portion, and
the adhesive layer is filled in the third pattern.

11. The foldable display device according to claim 1, further comprising:
a top coating layer on the cover glass,
wherein the folding area is outwardly folded such that a display surface of the foldable display device faces outside,
the cover glass includes a third pattern which is provided so as to correspond to the folding area,
the third pattern is formed of a plurality of grooves which is formed from the top surface to the bottom surface of the cover glass, and
the top coating layer is filled in the third pattern.

12. The foldable display device according to claim 11, wherein the organic material layers include:
an over coating layer on the plurality of color filters; and
an adhesive layer on the over coating layer, and
the second pattern is formed by a plurality of openings which passes through the over coating layer so as to correspond to the folding center area.

13. The foldable display device according to claim 12, wherein the plurality of openings of the over coating layer is located so as to overlap the plurality of grooves of the cover glass.

14. The foldable display device according to claim 11, wherein the organic material layers include:
an over coating layer on the plurality of color filters; and
an adhesive layer on the over coating layer, and
the second pattern is formed of a plurality of openings which passes through the adhesive layer so as to correspond to the folding center area.

15. The foldable display device according to claim 14, wherein each of the plurality of grooves of the cover glass located in the folding center area is connected to each of the plurality of openings of the adhesive layer.

16. The foldable display device according to claim 15, further comprising:
an etch stop layer disposed between the over coating layer and the adhesive layer.

17. The foldable display device according to claim 1, wherein the folding area includes a first folding area which is inwardly folded such that a display surface of the foldable display device faces the inside and a second folding area which is outwardly folded such that the display surface of the foldable display device faces the outside,
the first pattern includes a 1-1-th pattern provided so as to correspond to the first folding area and a 1-2-th pattern provided so as to correspond to the second folding area,
the second pattern includes a 2-1-th pattern provided so as to correspond to the first folding area and a 2-2-th pattern provided so as to correspond to the second folding area,
the 1-1-th pattern located in the first folding area has the same shape as the 1-2-th pattern of the second folding area and
the 2-1-th pattern located in the first folding area has the different shape from the 2-2-th pattern of the second folding area.

18. The foldable display device according to claim 17, wherein the organic material layers include:
an over coating layer on the plurality of color filters; and
an adhesive layer on the over coating layer, and
the 2-1-th pattern is formed of a plurality of 2-1-th openings which passes through the over coating layer so as to correspond to the folding shoulder area and
the 2-2-th pattern is formed of a plurality of 2-2-th openings which passes through the over coating layer so as to correspond to the folding center area.

19. The foldable display device according to claim 17, wherein the cover glass includes a 3-1-th pattern provided so as to correspond to the first folding area and a 3-2-th pattern provided so as to correspond to the second folding area, and
the 3-1-th pattern located in the first folding area has a different shape from the 3-2-th pattern of the second folding area.

20. The foldable display device according to claim 19, wherein the 3-1-th pattern is formed by a plurality of 3-1-th grooves which is formed from the bottom surface of the cover glass toward the top surface of the cover glass and
the 3-2-th pattern is formed by a plurality of 3-2-th grooves which is formed from the top surface of the cover glass toward the bottom surface of the cover glass.

21. A foldable display device including a folding area and non-folding areas located on both sides of the folding area, the folding area including folding shoulder areas located on both sides so as to be adjacent to the non-folding area and a folding center area located inside from the folding shoulder areas on both sides, the foldable display device comprising:
a glass substrate including a first pattern provided so as to correspond to the folding area;
a first bottom coating layer disposed on a bottom surface of the glass substrate and filled in the first pattern;
a display panel, on the glass substrate, which comprises light emitting diodes, a plurality of color filters and a black matrix; and
a cover glass on the plurality of color filters,
wherein one of organic material layers located between the plurality of color filters and the cover glass includes a pattern corresponding to the folding center area.
